(19) United States
(12) Patent Application Publication
(10) Pub. No.: US 2026/0023898 A1
(43) Pub. Date: Jan. 22, 2026

(54) SMART SPECIES IDENTIFICATION

(71) Applicants: BOARD OF TRUSTEES OF MICHIGAN STATE UNIVERSITY, East Lansing, MI (US); SAINT ANSELM COLLEGE, Manchester, NH (US); THE TEXAS A&M UNIVERSITY SYSTEM, College Station, TX (US)

(72) Inventors: Mariah MEEK, East Lansing, MI (US); Nadya MAMOOZADEH, East Lansing, MI (US); Shannon O'LEARY, Manchester, NH (US); Nihar MAHAPATRA, East Lansing, MI (US); David PORTNOY, College Station, TX (US)

(21) Appl. No.: 19/099,007

(22) PCT Filed: Jul. 27, 2023
(86) PCT No.: PCT/US2023/071151

§ 371 Date: Jan. 27, 2025

Related U.S. Application Data
(60) Provisional application No. 63/392,559, filed on Jul. 27, 2022.

(51) Int. Cl. G06F 30/27

(52) U.S. Cl. CPC G06F 30/27

(57) ABSTRACT

Methods and systems for species identification are disclosed. The methods and systems include: obtaining first, second, and third trained artificial intelligence (AI) models; obtaining one or more runtime images including a subject; determining a first confidence level of a morphological group of the subject based on the first AI model; determining a second confidence level of a species of the subject based on the morphological group and the second AI model; in response to the second confidence level being lower than a predetermined confidence level; performing a genomic test for the subject based on the determined morphological group or the determined species of the subject; and identifying the species of the subject based on a test result of the genomic test based on the third AI model. Other aspects, embodiments, and features are also claimed and described.

### CROSS-REFERENCE TO RELATED APPLICATION(S)

This application claims the benefit of U.S. Provisional Patent Application Ser. No. 63/392,559, filed Jul. 27, 2022, the disclosure of which is hereby incorporated by reference in its entirety, including all figures, tables, and drawings.

### STATEMENT REGARDING FEDERALLY SPONSORED RESEARCH

This invention was made with government support under 2137766 awarded by the National Science Foundation. The government has certain rights in the invention.

### SUMMARY

The following presents a simplified summary of one or more aspects of the present disclosure, to provide a basic understanding of such aspects. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In some aspects of the present disclosure, methods, systems, and apparatus for identifying animal subjects by their species and/or population, such as various fish and other aquatic species/populations are disclosed. These methods, systems, and apparatus may include steps or components for obtaining a first trained artificial intelligence (AI) model, a second trained AI model, and a third trained AI model; obtaining one or more runtime images including a subject; determining a first confidence level of a morphological group of the subject based on the first AI model and the one or more runtime images; determining a second confidence level of a species of the subject based on the morphological group, the second AI model, and the one or more runtime images, the second AI model receiving the morphological group and the one or more runtime images and producing the second confidence level of the species of the subject; in response to the second confidence level being lower than a predetermined confidence level, performing a genomic test for the subject based on the determined morphological group or the determined species of the subject; and identifying the species of the subject based on a test result of the genomic test based on the third AI model.

These and other aspects of the disclosure will become more fully understood upon a review of the drawings and the detailed description, which follows. Other aspects, features, and embodiments of the present disclosure will become apparent to those skilled in the art, upon reviewing the following description of specific, example embodiments of the present disclosure in conjunction with the accompanying figures. While features of the present disclosure may be discussed relative to certain embodiments and figures below, all embodiments of the present disclosure can include one or more of the advantageous features discussed herein. In other words, while one or more embodiments may be discussed as having certain advantageous features, one or more of such features may also be used in accordance with the various embodiments of the disclosure discussed herein. Similarly, while example embodiments may be discussed below as devices, systems, or methods embodiments it should be understood that such example embodiments can be implemented in various devices, systems, and methods.

### BRIEF DESCRIPTION OF THE DRAWINGS

FIG. 1 is a block diagram conceptually illustrating a system for smart species identification according to some embodiments.

FIG. 2 is a flow diagram illustrating an example process for species identification according to some embodiments.

FIG. 3 is a flow diagram illustrating an example process for species identification system training according to some embodiments.

FIG. 4 is a flow diagram illustrating an example process for species identification system training according to some embodiments.

FIG. 5 is an example graphical user interface for a user to upload one or more images to identify its species according to some embodiments.

FIG. 6 is an example graphical user interface to show a morphological group and a confidence level of the morphological group of the subject in one or more images according to some embodiments.

FIG. 7 is an example graphical user interface to show a species and a confidence level of the species of the subject in one or more images according to some embodiments.

FIG. 8 is an example graphical user interface to show a genomic test result and a confidence level of the genomic test result for the subject in one or more images according to some embodiments.

### DETAILED DESCRIPTION

The detailed description set forth below in connection with the appended drawings is intended as a description of various configurations and is not intended to represent the only configurations in which the subject matter described herein may be practiced. The detailed description includes specific details to provide a thorough understanding of various embodiments of the present disclosure. However, it will be apparent to those skilled in the art that the various features, concepts and embodiments described herein may be implemented and practiced without these specific details. In some instances, well-known structures and components are shown in block diagram form to avoid obscuring such concepts.

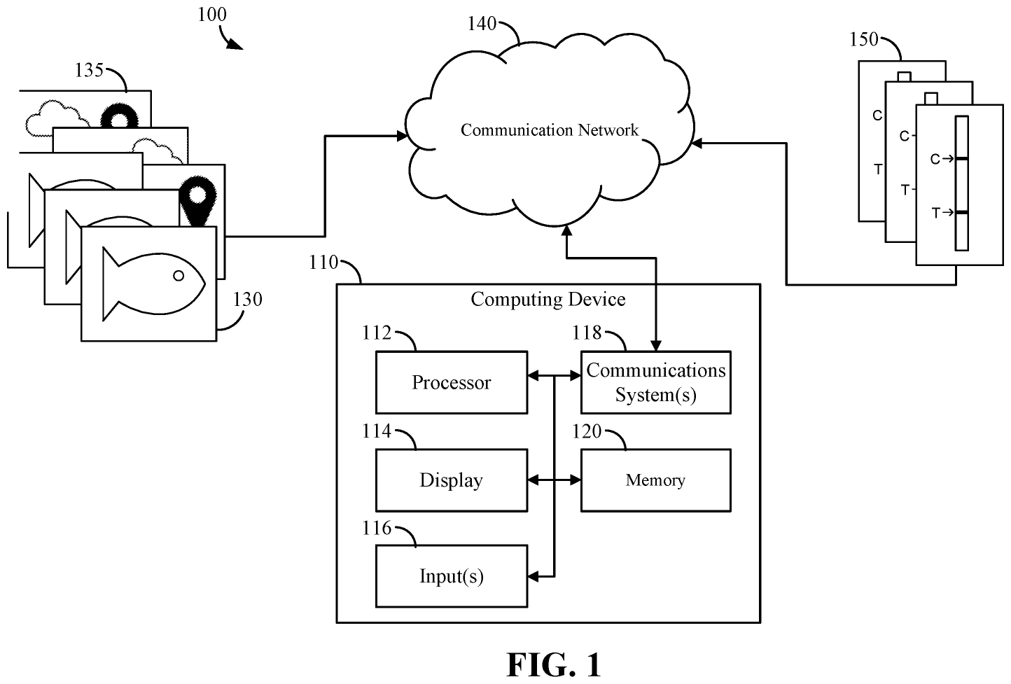

FIG. 1 shows an example 100 of a system for smart species identification in accordance with some embodiments of the disclosed subject matter. As shown in FIG. 1, a computing device 110 can receive one or more runtime images 130 including a subject to identify a morphological group of the subject and/or a species of the subject using a first artificial intelligent (AI) model and/or a second AI model. In some examples, the subject can be one or more fish. However, it should be understood that the subject can be animal(s), plant(s), and other suitable organism(s). In further examples, the computing device 110 can receive multiple training images 130 including a subject to train the first AI model and/or the second AI model. In non-limiting scenarios, the runtime images and/or training images can be obtained from (a) phone/tablet/other camera directly (including depth of field information for 3D data), (b) drone camera communicating wirelessly with a suitable app, which includes the system for smart species identification or is communicatively coupled to the system, (c) electronic monitoring streaming video or photos fed to the app, and (d) a public or private database.

In further examples, the computing device 110 can also receive one or more contextual features 135 of a runtime/training image to improve accuracy to predict a morphological group and/or species of the subject. For example, a contextual feature 135 of a runtime/training image can include metadata (e.g., location, time, resolution of the image, size of the image, or any other suitable information that the AI models exploit for the species identification). In further examples, a contextual feature 135 of a runtime/training image can further include weather information, temperature, weight, product type, and non-protected attributes of the entity involved (e.g., importer, fishery). In even further examples, a contextual feature 135 of a runtime/training image can further include vessel ID, time, sex, and size of fish (or other organism) specimen. It should be appreciated that the context feature 135 can be any other suitable information to improve the accuracy to predict a morphological group and/or a species of the subject.

In further examples, the computing device 110 can also receive one or more genomic test images or one or more genomic training images 150. In some examples, multiple genomic test images or genomic training images can be periodic time-series images of a test strip in a predetermined time and can show a progress to reach a test result of a genomic test. In other examples, the test strip can be independently used to identify a species of the subject.

In further examples, the computing device 110 can receive the one or more runtime/training images 130, contextual features 135, and/or genomic test images/genomic training images 150 over a communication network 140. In some examples, the communication network 140 can be any suitable communication network or combination of communication networks. For example, the communication network 140 can include a Wi-Fi network (which can include one or more wireless routers, one or more switches, etc.), a peer-to-peer network (e.g., a Bluetooth network), a cellular network (e.g., a 3G network, a 4G network, a 5G network, etc., complying with any suitable standard, such as CDMA, GSM, LTE, LTE Advanced, NR, etc.), a wired network, satellite communication network, etc. In some embodiments, communication network 208 can be a local area network, a wide area network, a public network (e.g., the Internet), a private or semi-private network (e.g., a corporate or university intranet), any other suitable type of network, or any suitable combination of networks. Communications links shown in FIG. 1 can each be any suitable communications link or combination of communications links, such as wired links, fiber optic links, Wi-Fi links, Bluetooth links, cellular links, etc.

In further examples, the computing device 110 can be any suitable computing device or combination of devices, such as a desktop computer, a laptop computer, a smartphone, a tablet computer, a wearable computer, a server computer, a computing device integrated into a vehicle (e.g., an autonomous vehicle), a camera, a robot, a virtual machine being executed by a physical computing device, etc. In some examples, the computing device 110 can train and run the first AI model, the second AI model, and/or third AI model. In other examples, the computing device 110 can include a first computing device for training the first AI model, the second AI model, and/or third AI mode and a second computing device for running the first AI model, the second AI model, and/or third AI model. In further examples, the computing device 110 can include a first computing device for the first AI model, a second computing device for the second AI model, and a third computing device for the third AI model. It should be appreciated that the training phase and the runtime phase of any combination of the first AI model, the second AI model, and the third AI model can be separately or jointly processed in the computing device 110 (including physically separated one or more computing devices). Although the system described here references three AI models (first, second, and third), alternative realizations of the system could be in the form of a sequence of one or more AI models or a hierarchy of AI models for species or trait identification.

In further examples, the computing device 110 can include a processor 112, a display 114, one or more inputs 116, one or more communication systems 118, and/or memory 120. In some embodiments, the processor 112 can be any suitable hardware processor or combination of processors, such as a central processing unit (CPU), a graphics processing unit (GPU), an application specific integrated circuit (ASIC), a field-programmable gate array (FPGA), a digital signal processor (DSP), a microcontroller (MCU), etc. In some embodiments, the display 114 can include any suitable display devices, such as a computer monitor, a touchscreen, a television, an infotainment screen, etc. In some embodiments, the input(s) 116 can include any suitable input devices and/or sensors that can be used to receive user input, such as a keyboard, a mouse, a touchscreen, a microphone, etc.

In further examples, the communications system(s) 118 can include any suitable hardware, firmware, and/or software for communicating information over communication network 140 and/or any other suitable communication networks. For example, the communications system(s) 118 can include one or more transceivers, one or more communication chips and/or chip sets, etc. In a more particular example, the communications system(s) 118 can include hardware, firmware and/or software that can be used to establish a Wi-Fi connection, a Bluetooth connection, a cellular connection, an Ethernet connection, etc.

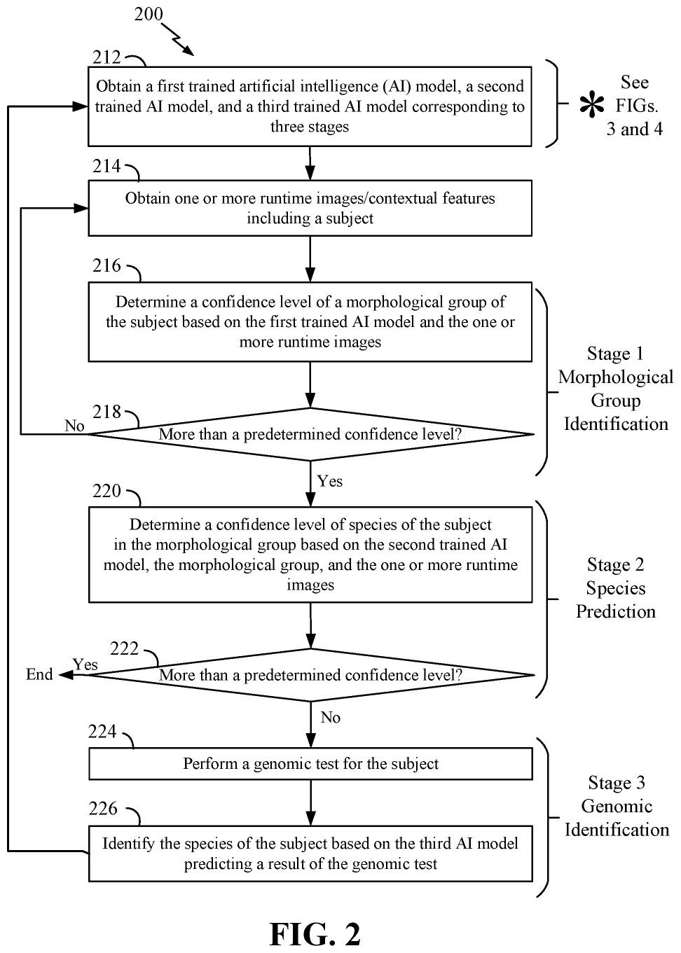

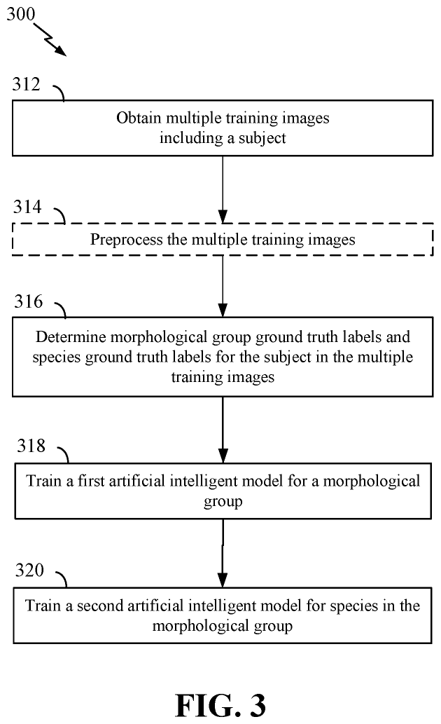

In further examples, the memory 120 can include any suitable storage device or devices that can be used to store image data, instructions, values, AI models, etc., that can be used, for example, by the processor 112 to perform species identification task to present content using display 114, to receive image sources via communications system(s) 118, etc. The memory 120 can include any suitable volatile memory, non-volatile memory, storage, or any suitable combination thereof. For example, memory 310 can include random access memory (RAM), read-only memory (ROM), electronically-erasable programmable read-only memory (EEPROM), one or more flash drives, one or more hard disks, one or more solid state drives, one or more optical drives, etc. In some embodiments, the memory 120 can have encoded thereon a computer program for controlling operation of computing device 110. For example, in such embodiments, the processor 112 can execute at least a portion of the computer program to perform one or more image processing and identification tasks described herein and/or to train/run AI models based on image sources (e.g., training/runtime images 130, contextual features 135, genomic test images/genomic training images 150, etc.) described herein, present content to the display 114, transmit/receive information via the communications system(s) 118, etc. As another example, processor 302 can execute at least a portion of processes 200, 300, and/or 400 described below in connection with FIGS. 2, 3, and/or 4.

In some examples, a mobile device can include the image sources 130, 135, 150 and the computing device 110. In other words, the equipment to be used for performing the imaging, classification, and user interface functions described herein can be a mobile device. For example, a user can take the one or more runtime/training images 130, obtain the contextual features 135, and/or obtain genomic test images/genomic training images 150 using the mobile device, and the mobile device can perform all or at least a portion of processes 200, 300, and/or 400 described below in connection with FIGS. 2, 3, and/or 4. In some embodiments, the mobile device may send images to a remote/cloud resource to run the classification algorithms described herein. In further examples, a ship or law enforcement vehicle/vessel can include an onboard camera and a computing device 110. The camera may be positioned so as to image fish as they are brought onboard, and alert operators of the vessel if the catch potentially contains endangered/protected species, or if the catch contains species other than the species intended to be caught. In this sense, the device can operate in an automatic or passive manner, which does not necessarily require user intervention to initiate a classification operation. For example, an onboard camera can take the one or more runtime/training images 130, contextual features 135, and/or genomic test images/genomic training images 150. In addition, the computing device 110 on a ship can perform at least a portion of processes 200, 300, and/or 400 described blow in connection with FIGS. 2, 3, and/or 4. In some embodiments, the device may generate a blockchain or other secure record to confirm the date, location, species caught, etc., which can then be provided to customers or to a customs/import or similar agency. Likewise, an alert that improper species were caught can be sent securely to a natural resources, fisheries or other governmental agency as appropriate. In other examples, the computing device 110 can transmit the image sources to another computing device via a communicating network 140. In yet further examples, the computing device 110 can further include a built-in genomic test platform. For example, one or more test strips can be enclosed in or disposed on a platform or other surface of the computing device 110 that holds or contacts the fish, and a solution can then be introduced to the strip to initiate the genomic test for the sample fish, as well as automatically acquiring one or more photographs of the result of the genomic test, and perform genomic identification based on a third AI model and the photographed result. In even further examples, a warehouse/marketplace can include a camera to capture the fish and/or the genomic test result and a computing device 110 to perform at least a portion of processes 200, 300, and/or 400 described blow in connection with FIGS. 2, 3, and/or 4. In even further examples, the lateral test strip can be embedded in a ship, marketplace, or floating sensor to collect environmental DNA (eDNA) and perform specific genetic tests when a classification algorithm performed on an associated monitoring camera detects a threshold likelihood that a fish species of interest may have entered the market or ship. Thus, the device may also contain an associated camera to capture a result of the genomic test, and perform genomic identification based on a third AI model and the photographed result.

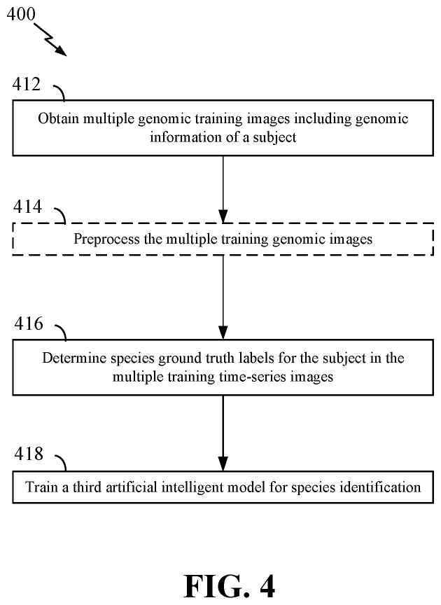

FIG. 2 is a flow diagram illustrating an example process 200 for species identification in accordance with some aspects of the present disclosure. As described below, a particular implementation can omit some or all illustrated features and may not require some illustrated features to implement all embodiments. In some examples, an apparatus (e.g., computing device 110) in connection with FIG. 1 can be used to perform the example process 200. However, it should be appreciated that any suitable apparatus or means for carrying out the operations or features described below may perform the process 200. The process 200 is generally directed to a runtime stage using trained artificial intelligence (AI) models. Training the AI models is described in connection with FIGS. 3 and 4.

At step 212, the process can obtain a first trained AI model, a second trained AI model, and a third trained AI model corresponding to three stages (e.g., stage 1:morphological group identification, stage 2: species prediction, and stage 3: genomic identification). In some examples, step 212 can be performed on a different apparatus for other steps in FIG. 2. In other example, step 212 can be performed on the same apparatus for other steps in FIG. 2. In a non-limiting scenario, the AI models can use convolutional neural networks (e.g., EfficientNet, LeNet, AlexNet, ZFNet, VGG, GoogLeNet, ResNet, Inception Net, Vision Transformer, or any other suitable neural networks for image recognition) and/or Fusion Feature Net (FNN). The training of the AI models is further elaborated in connection with FIGS. 3 and 4.

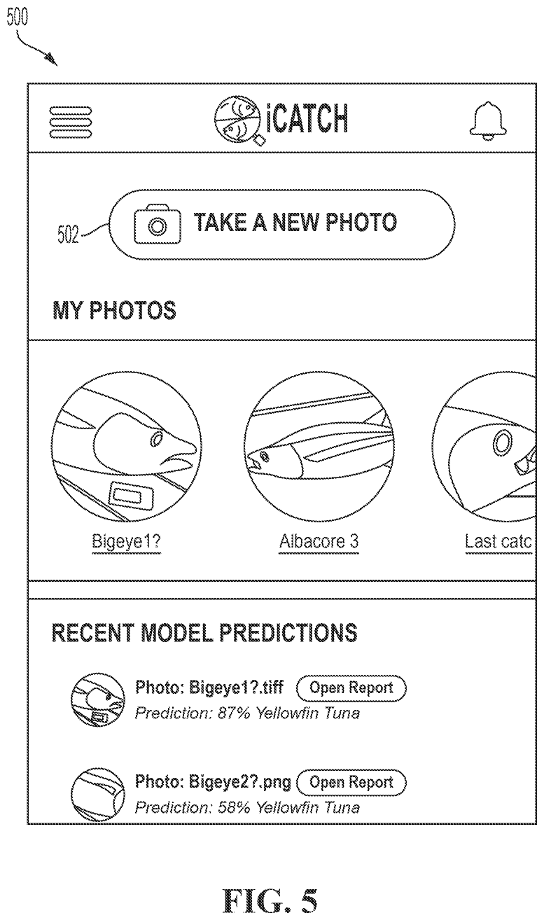

At step 214, the process can obtain one or more runtime images including a subject. In some examples, the subject is one or more fish. However, the subject can be any other suitable organism (e.g., animal, plant, etc.). In further examples, a runtime image can include a whole fish, multiple fish, or a part (e.g., a fillet, a fin, a mouth, a gill, scales, etc.) of the fish. For example, the one or more runtime images can be fed to the AI app from: (a) phone/tablet/other camera directly (including depth of field information for 3D data), (b) drone camera communicating wirelessly with the app, (c) electronic monitoring streaming video or photos fed to the app, (d) a test kit on which SHERLOCK test strips are developed—(d) is for the third AI model, (a) for the any of the three AI models, and (b) and (c) primarily for the first and second AI models. In some examples, a user can use a graphical user interface 502 to take a photo including a fish as shown in FIG. 5. In some examples, the example graphical user interface 502 can indicate where the user can take a photo of the fish. In further example, the graphical user interface 502 can request to take several photos of a fish corresponding to different parts of the fish to increase accuracy of identification of the fish. Then, the process can obtain the one or more runtime images via the application.

In some examples, a runtime image can be a two-dimensional picture including at least part of the fish. In further examples, one or more runtime images can be multiple still pictures or frames in a video. In other examples, the depth of field can be used in runtime images for three-dimensional view of fish (or some other organism) or fish part. In further examples, a runtime image can include multiple fish and other objects. For example, a drone or a camera on a ship can take a picture of a ship to capture a moment catching fish. In the example, the process can preprocess an image including multiple fish. For example, the preprocessing of the image can include cropping the picture including multiple fish to generate multiple runtime images. In further instances, the preprocessing of the image can further include resizing the image using rescaling, adjusting the contrast of the image, or performing any other suitable process converting the image into a suitable form that allows the AI models to process the image.

In some instances, the process can obtain one or more contextual features of a runtime image. For example, a contextual feature of a runtime image can include metadata of the runtime image for the AI models to utilize to identify the species of the subject. For example, the metadata can include a location at which the runtime image was taken, a time at which the runtime image was taken, a resolution of the runtime image, a size of the runtime image, or any other suitable information that the AI models exploit for the species identification. In further examples, a contextual feature of a runtime image can further include weather information, temperature, weight, product type, and non-protected attributes of the entity involved (e.g., importer, fishery). In even further examples, a contextual feature can further include vessel ID, time, water depth, water temperature, type of fishing technique used, water depth where fish was caught, sex, and size of fish (or other organism) specimen. These contextual features can be indicators to support morphological group identification and species identification given that species distributions reflect factors including geographic location and seasonality. In some examples, the user can manually input the contextual features (e.g., time and location information of the subject). In other examples, the process can automatically obtain the contextual features based on the metadata of the runtime image. For example, based on the location and time information of the runtime image, the process can access a public database to retrieve weather information and temperature information of the runtime image. In other examples, the process can access the vessel's or ship's computing device to retrieve location, water temperature and water depth information as contextual features. In other examples, the process can access local and remote databases to retrieve department, agency, company, shipment or import/export data as contextual features. In other examples, the user manually inputs the location and time information at which the user obtained the fish. In further examples, the process can identify that the location of the runtime image is an inland region remote from the sea. Then, the process can request the user to input the location and/or the time at which the user acquired the fish. In further examples, the process can obtain the entity information based on the location and time information of the runtime image. It should be appreciated that the contextual features are not limited to the list presented above. The process can obtain any other suitable contextual features to improve accuracy of identifying species of the fish in the runtime image.

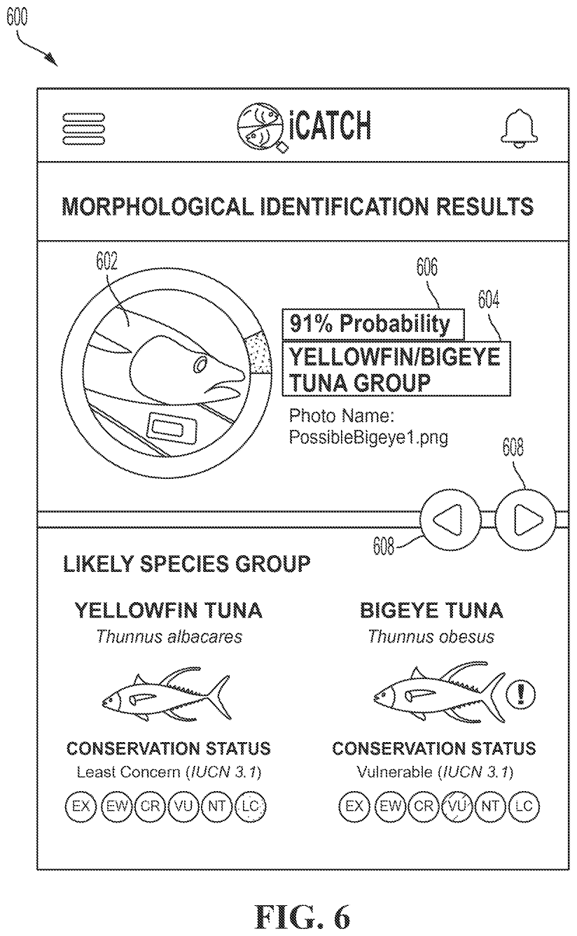

At steps 216 and 218, the process can perform stage 1 morphological group identification such that the process determines a morphological group of the fish with a confidence level. At step 216, the process can determine a confidence level of a morphological group of the subject based on the first trained AI model and the one or more runtime images. The first AI model is further described in FIG. 3. In some examples, FIG. 6 shows an example graphic user interface 600 showing a confidence level of a morphological group of the subject. Once the process obtains the one or more runtime images 602, the process can input the one or more runtime images 602 to the first trained AI model. Optionally, the process can additionally input the one or more contextual features to the first trained AI model. Based on the one or more runtime images 602, the first trained AI model can produce a morphological group 604 and a confidence level 606 of the morphological group 604 that the specimen/fish in the one or more runtime images 602 likely belong to. In a non-limiting instance, a confidence level of the first AI model can be a number between 0 and 1 or 0% and 100% to represent the likelihood that the fish in the one or more runtime images belongs to the morphological group 604.

In further examples, the first trained AI model can produce more than one morphological group with confidence levels corresponding to the morphological groups. For example, the example graphic user interface 600 can include one or more buttons to show other morphological groups with their confidence levels. Other morphological groups may have lower confidence levels than the confidence level 606 of the morphological group 604 on the main graphical user interface 600. In further examples, the first trained AI model can produce the morphological group 604 and the confidence level 606 of the morphological group 604 further based on the one or more contextual features. For example, the one or more contextual features can include the geographic location where the fish is acquired. If the fish can belong to morphological group A and morphological group B and fish in morphological group A does not live in the geographic location, the first trained AI model can decrease the confidence level of morphological group A for the fish. On the other hand, if fish in morphological group B lives in the geographic location, the first trained AI model can increase the confidence level of morphological group B for the fish. In further examples, the one or more contextual features can include the time information where the fish is acquired. If the fish can belong to morphological group C and morphological group D and fish in morphological group A is generally inactive in the season when the fish is acquired, the first trained AI model can decrease the confidence level of morphological group C for the fish. On the other hand, if fish in morphological group D becomes active in the season, the first trained AI model can increase the confidence level of morphological group D for the fish. In some examples, morphological groups are groups of species that appear visually similar to the untrained human eye, or sometimes even to the trained human eye, and hence for which additional aids (AI-based, genomics-based, human experts, or some combination thereof) are needed to tell them apart. One morphological group is the Bigeye and Yellowfin tuna group. Similarly, morphological groups for salmon, sharks, tunas, mobulids, snappers, groupers, shrimps, eels, etc. can be formed.

In further examples, the first AI model can not only produce prediction(s) of morphological group(s) and their confidence level(s), but also provide explanations of the prediction(s) in terms of morphological characteristics/keys detected in the image(s) showing image(s) of parts of the fish (organism) and an explanation of the characteristic(s) detected in that part. That is, the first AI model can not only answer “what” (is the morphological group/species), but also “why” the AI model thinks so. This is useful for inspiring confidence in the AI models (which are often blackbox models) by human users. It is also useful for training human observers/agents in learning how to identify species. In some examples, to provide explanations of the prediction(s) of the morphological group, the process can use a separate AI model to assess the prediction(s) of the morphological group(s). The separate AI model can include a large language model, a generative AI model, or any other suitable AI model.

At step 218, the process can determine whether the confidence level of the morphological group for the fish in the one or more runtime images is more than a predetermined confidence level. In some examples, a predetermined confidence level can be configurable based on the user. For example, a law enforcement officer may use a higher predetermined confidence level than a regular consumer for the morphological group determination. In some examples, the process can determine the predetermined confidence level for the morphological group of the fish based on a user profile (e.g., job, etc.) or a third-party information (e.g., law enforcement database). In other examples, the user can set the predetermined confidence level. When the confidence level of the morphological group is lower than the predetermined confidence level, the process can request the user to provide additional runtime image(s) and can move back to step 214. In other examples, when the confidence level of the morphological group is lower than the predetermined confidence level, the process can apply the one or more runtime images to another AI model for another morphological group. In such examples, multiple AI models corresponding to multiple morphological groups can be provided to determine a morphological group of the subject. Thus, in such examples, steps 216 and 218 can be repeated to find a right morphological group of the subject. In other examples, the first AI model can produce multiple confidence levels corresponding to multiple morphological groups for the subject. However, when the confidence level of the species is not lower than the predetermined confidence level, the process moves to step 220. In further examples, the process can process multiple specimens in the same image and produce two different morphological groups based on the multiple specimens. Then, the process can indicate that two competing morphological groups are predicted for the same fish and request the user to retake the runtime images or perform the genomic test at step 224.

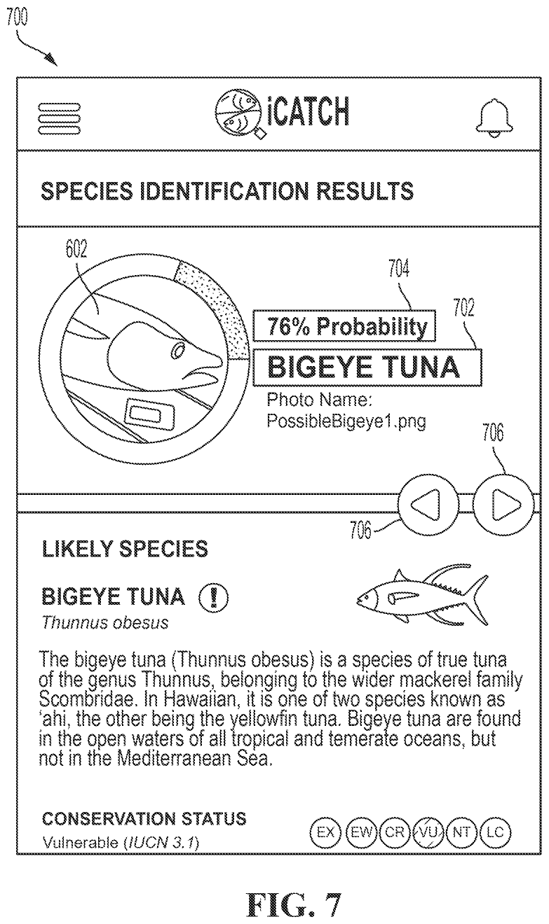

At steps 220 and 222, the process can perform stage 2 species prediction such that the process predicts a species of the fish with a confidence level of the species. At step 220, the process can determine a confidence level of a species for the subject based on the second trained AI model, the morphological group, and the one or more runtime images. Since the second trained AI model identifies species among the determined morphological group, the second trained AI model can reduce time and resource to determine a confidence level of a species for the subject. The second AI model is further described in FIG. 3. In some scenarios, multiple second trained AI models can exist for corresponding multiple morphological groups. Thus, the process can determine a second trained AI model based on the specific morphological group determined at step 216 and perform species prediction with the corresponding second AI model. In other examples, the second AI model can include one AI model to predict a species of the subject with the morphological group of the subject. That is, the first and second models can be combined into a single (multi-task) AI model that predicts both morphological group and species (along with other traits as indicated above.). In some examples, FIG. 7 shows an example graphic user interface 700 showing a confidence level of a species of the subject. Once the process obtains the one or more runtime images 602 and the morphological group 604 with the highest confidence level determined at step 216, the process can input the one or more runtime images 602 and the morphological group 604 to the second trained AI model. Optionally, the process can additionally input the one or more contextual features to the second trained AI model. Based on the one or more runtime images 602 and the morphological group 604, the second trained AI model can produce a species 702 and a confidence level 704 of the species 702 that the specimen/fish in the one or more runtime images 602 likely belongs to. In a non-limiting instance, a confidence level of the second AI model can be a number between 0 and 1 or 0% and 100% to represent the likelihood that the fish in the one or more runtime images belongs to the species 702.

In further examples, the second trained AI model can produce more than one species with confidence levels corresponding to the species. For example, the example graphic user interface 700 can include one or more buttons 706 to show other species with their confidence levels. Other species can have lower confidence levels than the confidence level 704 of the species 702 on the main graphical user interface 700. In further examples, the second trained AI model can produce the species 702 and the confidence level 704 of the species 702 further based on the one or more contextual features. For example, the one or more contextual features can include the geographic location where the fish is acquired. If the fish can belong to species A and species B and fish in species A does not live in the geographic location, the second trained AI model can decrease the confidence level of species A for the fish. On the other hand, if fish in species B lives in the geographic location, the second trained AI model can increase the confidence level of species B for the fish. In further examples, the one or more contextual features can include the time information where the fish is acquired. If the fish can belong to species C and species D and fish in species A is generally inactive in the season when the fish is acquired, the second trained AI model can decrease the confidence level of species C for the fish. On the other hand, if fish in species D becomes active in the season, the second trained AI model can increase the confidence level of species D for the fish.

In further examples, the second AI model can not only produce prediction(s) of species and their confidence level(s), but also provide explanations of the prediction(s) in terms of species characteristics/keys detected in the image(s) showing an image of parts of the fish (organism) and an explanation of the characteristic(s) detected in that part. That is, the second AI model can not only answer “what” is the species, but also “why” the AI model thinks so. This is useful for inspiring confidence in the AI models and for training human observers/agents in learning how to identify species.

In further examples, the second trained AI model can identify a mislabeled species (e.g. Atlantic salmon being mislabeled as sockeye salmon). For example, the second trained AI model can identify Pacific salmonids to also include sockeye salmon (Oncorhynchus nerka), coho salmon (O. kisutch), chinook salmon (O. tshawytscha), pink salmon (O. gorbuscha), chum salmon (O. keta), and rainbow trout (O. mykiss). In addition, the second trained AI model can also distinguish threatened sharks in the genus Sphyrna (scalloped hammerhead (S. lewini), Carolina hammerhead (S. gilberti), great hammerhead (S. mokarran), and smooth hammerhead (S. zygaena)). Furthermore, the second trained AI model can identify Thunnus tunas that support key domestic and international fisheries (bigeye tuna (T. obesus), yellowfin tuna (T. albacares), albacore tuna (T. alalunga), Atlantic bluefin tuna (T. thynnus), Pacific bluefin tuna (T. orientalis), and southern bluefin tuna (T. maccoyii). In addition, the second trained AI model can distinguish Pacific whiteleg shrimp from other commonly marketed species (pink shrimp (Farfantepenaeus duorarum), brown shrimp (F. aztecus), white shrimp (Litopenaeus setiferus]), and black tiger shrimp (P. monodon)). However, it should be appreciated that the species listed above are a mere example. For example, the second trained AI model can identify eels (e.g., Anguilid eels), paneid shrimp, Mobulid rays, and the snapper/grouper complex (Serranidae/lutjanidae), additional oceanic shark species, and/or any other suitable species. In further examples, the second trained AI model can identify and distinguish other types of fish, animals, plants, and other suitable organisms if the second AI model is trained with corresponding types of organisms.

At step 222, the process can determine whether the confidence level of the species for the fish in the one or more runtime images is more than a predetermined confidence level. In some examples, a predetermined confidence level can be configurable based on the user. For example, a law enforcement officer may use a higher predetermined confidence level than a regular consumer for the morphological group determination. In some examples, the process can determine the predetermined confidence level for the morphological group of the fish based on a user profile (e.g., job, etc.) or a third-party information (e.g., law enforcement database). In other examples, the user can set the predetermined confidence level. In some examples, the predetermined confidence level for the species may be lower than the predetermined confidence level for the morphological group because the confidence level of the morphological group with a broader scope is generally higher than the confidence level of the species. When the confidence level of the species is higher than the predetermined confidence level, the process is complete. However, when the confidence level of the species is not higher than the predetermined confidence level, the process moves to step 224. In further examples, the process can process multiple specimens in the same image and highlight/direct the user to perform genomic tests on those specimens most likely to belong to species/specimen of most concern. For example, the process can predict species A based on a fin of the fish in the runtime image and predict species B based on a fillet of the fish in the runtime image. Then, the process can indicate that two species are predicted for the same fish and request the user to perform the genomic test at step 224.

At steps 224 and 226, the process can perform stage 3 genomic identification to identify the species of the fish. At step 224, the process or the user can perform a genomic test for the subject (i.e., fish). In some examples, the genomic test can be performed based on the results at steps 216 and/or 220. For example, the genomic test can be performed for species in the morphological group determined at step 216, and/or for species in the species predicted at step 220 when the confidence level from the second AI model is not sufficient to determine the species. Thus, the morphological group identification and the species prediction stages can act as filters to rule out the need for the genomic test. In some examples, the genomic test can use Clustered Regularly Interspaced Short Palindromic Repeats-Associated Protein 13 (CRISPR-CAS13) with isothermal amplification to produce the Specific High-Sensitivity Enzymatic Reporter UnLOCKing (SHERLOCK) molecular detection platform. The process can identify the specific regions of the genome that distinguish different species, and then design the SHERLOCK assays around that. For example, the genomic test can pair a SHERLOCK rapid genomic test with extraction-free DNA isolation so that species can be genetically identified by swabbing a specimen (e.g., fish) and applying in the swab to a test strip.

In some examples, the SHERLOCK test can detect single base pair differences (e.g., single nucleotide polymorphisms; SNPs) among samples at very low DNA copy numbers. The Sherlock genomic test can include forward and reverse recombinase polymerase amplification (RPA) primers for isothermal amplification of target DNA and a CRISPR RNA (crRNA) for diagnostic SNP detection. Then, lateral flow strips can be used for the genomic test based on the optimal combination of primers and crRNA for each species. The lateral flow strips enable equipment-free detection based on a color-change reaction visible to the human eye. In some examples, the user can swab the surface of a sample, swirl in buffer, and apply the swab to a test strip. In further examples, the sample can include the fish in the one or more runtime images. Also, the sample can also include the fresh and frozen whole fish, fillets, and other parts of the fish. This method requires no specialized equipment or expertise and provides results more quickly (less than 30 minutes) than conventional extraction-based methods. In some examples, one or two lines gradually appear on the lateral strip generally in less than 30 minutes. One line (C) indicates that whether the test is working properly while another line (T) indicates that whether the sample is the same species as the target species. For example, the first AI model indicates that the fish is in the salmon morphological group, but the second AI model does not indicate that the fish is an Atlantic salmon with sufficient confidence. Then, the genomic test using a lateral strip can identify that the fish is an Atlantic salmon.

In some examples, the morphological predictions as well as the species predictions can be used to tell the user which test strip to use. This can combine the output of two different models to help determine 1, 2, or more test strips to be applied. In some embodiments, it may even ask the user to use a counter strip to rule out a species, and then that can impact the output of the models (e.g., if the user does not have the right strip on hand, but you can rule out a specific species of tuna, that might tell the model that it is more likely another specific species.).

In some examples, a number of (periodic) genomic runtime images (e.g., snapshots) of a test strip can be taken and can be provided to the third AI model as it develops from the start of the test (time 0) till the time when the third AI model produces a prediction. In further examples, the third AI model, with user permission, can keep track of whether a given user is performing SHERLOCK tests properly and can prompt the user to view a training video on how to perform the test properly, with an explanation of which aspect of the test they are likely not performing properly. It can also prompt the user to perform a second (or third) SHERLOCK test to increase the accuracy of the test, as needed.

However, it should be appreciated that the genomic test is not limited to the lateral flow strip. For example, a device including multiple lateral strips can identify a species of the fish. In some examples, one of the multiple lateral strips shows a positive result indicating that the fish is the same species of the target species in the lateral strip, and other lateral strips show a negative result indicating that the fish is not matched with the target species for other lateral strips. In other examples, one lateral strip is designed to show one ‘C’ line (control) and multiple ‘T’ lines at predetermined positions in the lateral strip. Each ‘T’ line can indicate a different target species. In further examples, the lateral strip with multiple ‘T’ lines can indicate multiple species in a species group. For example, the lateral strip can be a tuna strip for all the salmon targets (Salmo salar and all other Oncorhynchus species), a shark strip for all the shark targets, a ray strip for all the ray targets, or any other strip for different species in a species group. In other examples, the genomic test can be performed by an electronic device to identify the species of the fish of interest.

At step 226, the process can identify the species of the subject based on the third AI model predicting a result of the genomic test. In some examples, the genomic test can gradually produce a test result (e.g., positive or negative) on a test strip generally in less than 30 minutes. However, the third trained AI model as an AI-informed time series forecasting model, can reduce the turn-around time for the test result. For example, the third AI model can receive the genomic test information. The genomic test information may include a target species for the lateral strip. The third AI model can provide a predicted time to get a test result with more than a predetermined confidence level. For example, the third AI model can produce different times for an Atlantic salmon and a Thunnus tuna to get a test result with more than 95% confidence level. After the time period that the third AI model calculated for the target species, the process can receive a genomic test image showing the lateral strip including one or more lines. Based on the genomic test image and the target species information, the third AI model can produce a test result (e.g., positive, negative, or identified species) with a confidence level for that test result. In other examples, the genomic test can be exploited to compare a sample to a target species without using the third AI model. In further examples, the third AI model can be used in a hierarchical approach to predict a species from more general to more specific species or even stock level. For example, the third AI model can be exploited based on the result of the first AI model and/or the second model. Thus, the third AI model can produce a species prediction with a confidence level among species in a morphological group from the first AI model and/or several species candidates from the second AI model. In a non-limiting scenario, the final prediction of interest from the third AI model may be the species level, some level higher (say, genus), or level lower (e.g., stock). However, it should be appreciated that the third AI model is not limited to a hierarchical model. For example, the third AI model can directly perform the species prediction without using the result from the first or second AI model, especially when the AI app is used independently of the genomic test. In further examples, the genomic test can identify and distinguish other types of fish, animals, plants, and other suitable organisms. In even further examples, the third trained AI model can identify and distinguish other types of fish, animals, plants, and other suitable organisms if the second AI model is trained with corresponding types of organisms. In some examples, results of the genomic tests can be fed to all three AI models (i.e., the first AI model, the second AI model, and the third AI model) to continually improve them with the runtime images.

In further examples, the third AI model can, given a genomic test image (e.g., snapshot) of a developing test strip, can predict: (a) the eventual test strip outcome (positive or negative) and the confidence level of the prediction, (b) the amount of time remaining for reliable naked eye readout, and the confidence level of that prediction, (c) the amount of time remaining for AI prediction to reach a given confidence level, and (d) the quantity of DNA in the sample used for the test and confidence in the prediction.

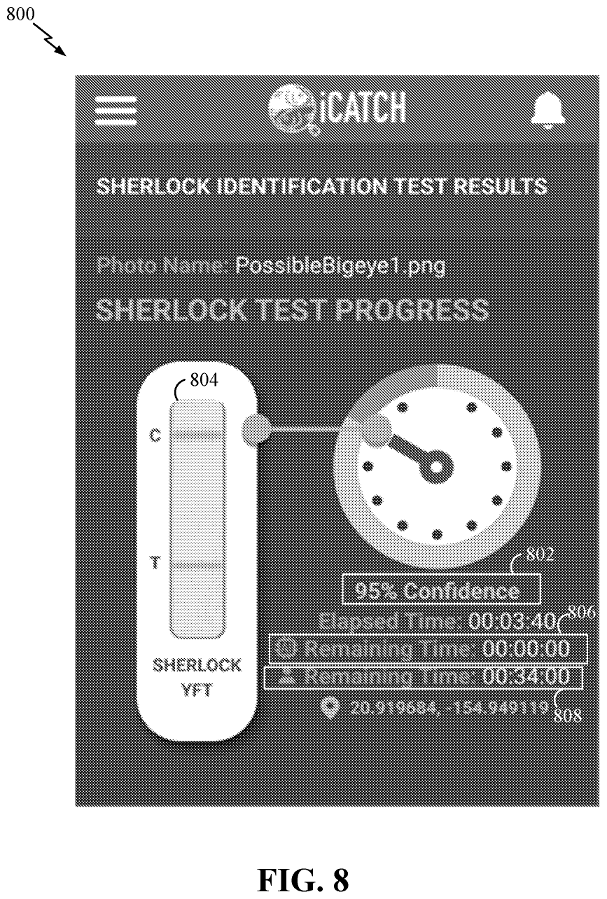

In some examples, FIG. 8 shows an example graphic user interface 800 showing a confidence level of a test result. In addition, the example graphic user interface 800 can show the genomic test image 804. In some examples, the third AI model can produce the amount of time 806 remaining for AI prediction to reach a given confidence level and the amount of time 808 remaining for reliable naked eye readout. In some examples, the process can receive the genomic test image 804 after the time 806 that the third AI model calculated. In other examples, the process can receive the genomic test image 804 every predetermined time period or one genomic test image 804. In further examples, the process can receive a video including multiple genomic test images 804. The level of the darkness of the line on the strip can vary depending on the type of fish of interest. This may result in a different interpretation for a different user. However, the third AI model can produce a quantified confidence level of the result.

In some examples, when the third AI model provides a confidence level of the test result, which is lower than a predetermined confidence level, the process moves back to step 212 to obtain the first, second, and third AI models, and perform stages 1, 2, and 3 for morphological group/species identification at steps 214-226.

In some examples, the genomic test image 804 can be taken by a user and can be provided to the third AI model. In other examples, remote genomic testing can be performed. For example, the genomic test image 804 can be taken by the genomic test image 804 can be automatically taken by a robot or drone. The remote genomic testing can be used on organisms in the water or on a deck, or dock without a human having to handle the testing.

FIG. 3 is a flow diagram illustrating an example process 300 for morphological group and species identification training in accordance with some aspects of the present disclosure. As described below, a particular implementation can omit some or all illustrated features and may not require some illustrated features to implement all embodiments. In some examples, an apparatus (e.g., computing device 110) in connection with FIG. 1 can be used to perform the example process 300. However, it should be appreciated that any suitable apparatus or means for carrying out the operations or features described below may perform the process 300. The process 300 is generally directed to a training stage of artificial intelligence (AI) models for morphological group identification and species prediction.

At step 312, the process can obtain multiple training images including a subject. The subject can include fish. However, the subject can be any other suitable organism. In some examples, a training image can include a whole fish, or a part (e.g., a fillet, a fin, a mouth, a gill, scales, etc.) of the fish. The training images can be taken from diverse seafood products (e.g., whole fish, fillets, fins, etc.), from various angles, and under different settings allowing a first AI model and a second AI model to differentiate morphological groups and species, respectively, under realistic field conditions. In some examples, the process can obtain the multiple training images (e.g., with or without ground truth labels) from a public database. In other examples, the process can obtain the multiple training images directly from a third party. In even further examples, the process can obtain the multiple training images from: (a) phone/tablet/other camera directly (including depth of field information for 3D data), (b) drone camera communicating wirelessly with the app, (c) electronic monitoring streaming video or photos fed to the app. In a non-limiting scenario, a person on a ship can take a picture including fish (e.g., with or without ground truth labels) and the process can obtain (e.g., in real-time, in a periodic manner, etc.) the picture with or without ground truth labels.

At step 314, the process can optionally preprocess the multiple training images. For example, the preprocessing of the image can include cropping the picture including multiple fish to generate multiple training images by cropping the picture, each including a fish. In further instances, the preprocessing of the image can further include resizing the image using rescaling, adjusting the contrast of the image, or performing any other suitable process converting the image into a suitable form that allows the AI models to process the image. In some examples, the preprocessing of the image can include data augmentation by generating new training images based on the existing images. In a non-limiting example, a new training image can be generated by shifting an existing image, scaling an existing image, flipping an existing image, rotating an existing image, translating an existing image, and/or adding noise to an existing image. However, it should be appreciated that new training images can be generated by any other suitable data augmentation technique.

At step 316, the process can determine morphological group ground truth labels and species ground truth labels for the subject in the multiple training images. In a non-limiting example, a training image can include an Atlantic salmon, a sockeye salmon (Oncorhynchus nerka), a coho salmon (O. kisutch), a chinook salmon (O. tshawytscha), a pink salmon (O. gorbuscha), a chum salmon (O. keta), a rainbow trout (O. mykiss), a scalloped hammerhead (S. lewini), a Carolina hammerhead (S. gilberti), a great hammerhead (S. mokarran), a smooth hammerhead (S. zygaena), a bigeye tuna (T. obesus), a yellowfin tuna (T. albacares), an albacore tuna (T. alalunga), an Atlantic bluefin tuna (T. thynnus), a Pacific bluefin tuna (T. orientalis), a southern bluefin tuna (T. maccoyii), a Pacific whiteleg shrimp (Litopenaeus vannamei), a pink shrimp (Farfantepenaeus duorarum), a brown shrimp (F. aztecus), a white shrimp (Litopenaeus setiferus), or a black tiger shrimp (P. monodon). Of course, it should be appreciated that the species listed above are a mere example. The training image can include any other suitable type of fish, animal, plant, and other suitable organisms. In some examples, a person having ordinary skill in the art can identify the individual species in the training image and label the species in the training image. In other examples, the process can access a database to retrieve training images with ground truth labels. In some instances, the process can determine species ground truth labels for multiple training images and does not generate morphological group ground truth labels on the multiple training images. Then, the process can identify morphological groups for multiple training images by accessing a lookup table in the memory to map each species to a morphological group. In other instances, the process can determine species ground truth labels and morphological group ground truth labels on multiple training images.

At step 318, the process can train a first AI model for a morphological group. In some examples, the process can provide multiple training images with their morphological ground truth labels to the first AI model. In further examples, visual features in training images can be captured using deep convolutional neural networks (CNN) and EfficientNet/VGG-16. Next, all features can be concatenated and input to feed-forward layers for classification. In some examples, the first AI model can include other CNN (e.g., LeNet, AlexNet, ZFNet, VGG, GoogLeNet, ResNet, Inception Net, Vision Transformer, or any other suitable neural networks for image recognition). In even further examples, the first AI model can process the multiple training images to correlate the processed output against the ground truth labels. Based on the correlation, the process can modify and train the first AI model. In further examples, the process can additionally provide one or more contextual features to the first AI model for training. For example, a contextual feature of a training image can include metadata of the runtime image for the first AI models to utilize to identify the morphological group of the subject. For example, the metadata can be a location in which the training image was taken, a time at which the training image was taken, a resolution of the training image, a size of the training image, or any other suitable information that the first AI model can exploit for the morphological group identification. In further examples, a contextual feature of a training image can further include weather information, temperature, weight, product type, and non-protected attributes of the entity involved (e.g., importer, fishery). In some examples, the ground truth label can include the contextual features (e.g., time and location information of the subject). In other examples, the process can retrieve the contextual features based on the metadata of the training image. For example, based on the location and time information of the training image, the process can access a public database to retrieve weather information and temperature information of the runtime image. In other examples, the location and time information at which the fish is obtained can be manually provided. It should be appreciated that the contextual features are not limited to the list presented above. The process can obtain any other suitable contextual features to improve accuracy of identifying the morphological group of the fish in an image. After training the first AI model, the first trained AI model can produce a morphological group and a confidence level of the morphological group for the subject in an image. For example, the first trained AI model can determine whether an input fish image corresponds to one of four morphologically similar tuna species (albacore, yellowfin, skipjack, and bigeye). Of course, the type of morphological groups is not limited to the example above.

At step 320, the process can train a second AI model for a species in the morphological group determined by the first AI model. In some examples, the second AI model can be interconnected with the first AI model such that the second AI model receives the output of the first AI model. In a non-limiting scenario, the second AI model can be trained along with the first AI model. In another non-limiting scenario, the second AI model and the first AI model can be separately trained in a parallel manner. For example, the process can provide multiple training images with species ground truth labels and morphological group ground truth labels corresponding to the multiple training images. In some examples, the second AI model can include any suitable machine learning algorithm (e.g., EfficientNet, LeNet, AlexNet, ZFNet, VGG, GoogLeNet, ResNet, Inception Net, or any other suitable neural networks for image recognition). In further examples, the second AI model can process the multiple training images to correlate the processed output against species ground truth labels and morphological group ground truth labels. Based on the correlation, the process can modify and train the second AI model. After training the second AI model, the second trained AI model can produce a species in the morphological group and a confidence level of the species for the subject in an image. In some examples, the first and second AI models can be trained to predict species or some other taxonomic level, e.g., genus (less specific) or stock (more specific). In further examples, the first and/or second AI model can be trained to predict traits other than species, e.g., weight, sex, disease, size, life stage, quantity (catch amount), etc.

FIG. 4 is a flow diagram illustrating an example process 400 for genomic identification training in accordance with some aspects of the present disclosure. As described below, a particular implementation can omit some or all illustrated features and may not require some illustrated features to implement all embodiments. In some examples, an apparatus (e.g., computing device 110) in connection with FIG. 1 can be used to perform the example process 400. However, it should be appreciated that any suitable apparatus or means for carrying out the operations or features described below may perform the process 400. The process 400 is generally directed to a training stage of an artificial intelligence (AI) model for genomic identification. In further examples, the process can additionally provide one or more contextual features to the second AI model for training.

At step 412, the process can obtain multiple genomic training images including genomic information of a subject. In some examples, the genomic information can include a test result on a lateral flow strip. The test result on a lateral flow strip is elaborated at step 224 of FIG. 2. In some examples, the multiple genomic training images can include time-series images for the subject. For example, the genomic test can gradually produce a test result (e.g., positive or negative) on a test strip in less than 30 minutes. Thus, multiple genomic training images over a predetermined period (e.g., 30 minutes, 40 minutes, etc.) of time can correspond to one genomic test with a test strip. For example, a genomic training image can be taken (e.g., every 5 minutes, 2 minutes, 1 minute, 30 seconds, etc.) over the predetermined period of time (e.g., 30 minutes, 40 minutes, etc.). In other examples, one video including the multiple genomic training images can be used for one genomic test. In further examples, the genomic information can include any other suitable information using any suitable test. In some scenarios, the process can obtain multiple genomic training images from: (a) phone/tablet/other camera directly (including depth of field information for 3D data), and/or (b) a test kit on which SHERLOCK test strips are developed.

However, it should be appreciated that the genomic test is not limited to the lateral flow strip. For example, a device including multiple lateral strips can identify a species of the fish. In some examples, one of the multiple lateral strips shows a positive result indicating that the fish is the same species of the target species in the lateral strip, and other lateral strips show a negative result indicating that the fish is not matched with the target species for other lateral strips. In other examples, one lateral strip is designed to show one ‘C’ (control) line and multiple ‘T’ lines at predetermined positions in the lateral strip. Each ‘T’ line can indicate a different target species. In other examples, the genomic test can be performed by an electronic device to identify the species of the fish of interest. The multiple genomic training images can reflect results of these genomic tests.

At step 414, the process can preprocess the multiple training genomic images. The preprocessing of the multiple training genomic images can be similar to the preprocessing of the multiple training images at step 314 of FIG. 3.

At step 416, the process can determine genomic test ground truth labels for the subjects in the multiple training genomic images. Thus, the third AI model can read and predict the outcome of the genomic lateral flow test strip to identify species. In some examples, the genomic test ground truth labels can be applied to time-series images for one genomic test. During the training phase of the third AI model, a number of (periodic) genomic training images (e.g., snapshots) of a test strip can be taken as it develops from the start of the test (time 0) till beyond the time required for easy human read-out of the results (1 hour or more), i.e., a single lateral flow test produces multiple training records. For a given test strip, all genomic training images (i.e., snapshots) can be labeled with the same final positive/negative outcome once the test strip fully develops. In addition to labeling each training record with the eventual positive/negative test outcome, it can also be labeled with the amount of time remaining for reliable read-out by naked eye and the quantity of DNA in the sample used for the lateral flow strip. Multiple training records are obtained similarly for a large number of lateral flow tests to create a training dataset for the third AI model.

At step 418, the process can train a third AI model for species identification. In some examples, the process can provide the multiple training genomic images with corresponding genomic test ground truth labels to the third AI model. The third AI model provides a time to identify the target species based on the multiple genomic training images and a predicted test result with a confidence level of the predicted test result. Thus, the third AI model can be trained on both positive and negative test results for each species and can predict the final test outcome and associated confidence in real-time based on images of the SHERLOCK test strip. In some examples, the third AI model used for time series forecasting to predict the SHERLOCK test outcome can utilize images of test strips in the early stages of SHERLOCK testing. The third AI model architecture used can be a combination of a CNN for visual features and a generative adversarial network (GAN), which will generate the next sequence of test outcomes over time. Data related to model input features (both visual and contextual) as well as success and failure of prediction are sent from each user with permission to the model on the cloud. In some examples, the third AI model can be trained to predict species or some other taxonomic level, e.g., genus (less specific) or stock (more specific). Once trained on this dataset, the third AI model can, given a snapshot of a developing test strip, predict: (a) the eventual test strip outcome (positive or negative) and the confidence level of the prediction, (b) the amount of time remaining for reliable naked eye readout, and the confidence level of that prediction, (c) the amount of time remaining for AI prediction to reach a given confidence level, and (d) the quantity of DNA in the sample used for the test and confidence in the prediction. Thus, the third trained AI model can learn to read the genomic test results on the lateral flow strip and can predict the final result (positive or negative) of the strip, the time remaining for reliable readout by naked eye, and time remaining for reliable readout by AI based on a confidence level. The third trained AI model can also be trained to predict the amount of target DNA on the test strip (i.e., not only presence/absence, but also quantification), which may potentially be useful in some applications to provide an indication of the amount of DNA present in the sample.

In the foregoing specification, implementations of the disclosure have been described with reference to specific example implementations thereof. It will be evident that various modifications may be made thereto without departing from the broader spirit and scope of implementations of the disclosure as set forth in the following claims. The specification and drawings are, accordingly, to be regarded in an illustrative sense rather than a restrictive sense.

What is claimed is:

1. A method for species identification, comprising:
obtaining a first trained artificial intelligence (AI) model, a second trained AI model, and a third trained AI model;
obtaining one or more runtime images including a subject;
determining a first confidence level of a morphological group of the subject based on the first AI model and the one or more runtime images;
determining a second confidence level of a species of the subject based on the morphological group, the second AI model, and the one or more runtime images, the second AI model receiving the morphological group and the one or more runtime images and producing the second confidence level of the species of the subject;
in response to the second confidence level being lower than a predetermined confidence level, performing a genomic test for the subject based on the morphological group or the species of the subject; and
identifying the species of the subject based on a test result of the genomic test based on the third AI model.

2. The method of claim 1, wherein the determining of the first confidence level of the morphological group of the subject comprises:
determining a highest confidence level of the morphological group among a plurality of confidence levels corresponding to a plurality of morphological groups, the highest confidence level comprising the first confidence level.

3. The method of claim 1, further comprising:
determining the second AI model among a plurality of AI models corresponding a plurality morphological groups based on the morphological group of the subject.

4. The method of claim 2, further comprising:
applying the one or more runtime images to the first AI model; and
receiving a plurality of confidence levels corresponding to the plurality of morphological groups, the first confidence level being included in the plurality of confidence levels.

5. The method of claim 1, further comprising:
applying the morphological group, the one or more runtime images, and one or more contextual features to the second AI model, and
receiving the second confidence level of the species of the subject based on the morphological group, the one or more runtime images, and the one or more contextual features.

6. The method of claim 5, wherein the one or more contextual features comprises metadata of the one or more runtime images.

7. The method of claim 5, wherein the one or more contextual features comprises at least one of: a location at which the one or more runtime images was taken, a time at which the one or more runtime images was taken, weather information at which the one or more runtime images was taken, temperature information at which the one or more runtime images was taken, or vessel information.

8. The method of claim 1, wherein the determining of the second confidence level of the species of the subject comprises:
determining a highest confidence level of the species among a plurality of confidence levels corresponding to a plurality of species, the highest confidence level comprising the second confidence level.

9. The method of claim 1, further comprising:
providing a genomic test image of the test result of the genomic test to the third AI model,
wherein the species of the subject is identified based on a prediction result of the third AI model

10. The method of claim 9, wherein the test result is whether the subject is a same species as a target species.

11. A system for species identification, comprising:
a memory; and
a processor communicatively coupled to the memory,
wherein the memory stores a set of instructions which, when executed by the processor, causes the processor to:
obtain a first trained artificial intelligence (AI) model, a second trained AI model, and a third trained AI model;
obtain one or more runtime images including a subject;
determine a first confidence level of a morphological group of the subject based on the first AI model and the one or more runtime images;
determine a second confidence level of a species of the subject based on the morphological group, the second AI model, and the one or more runtime images, the second AI model receiving the morphological group and the one or more runtime images and producing the second confidence level of the species of the subject;
in response to the second confidence level lower than a predetermined confidence level, perform a genomic test for the subject based on the determined morphological group or the determined species of the subject; and
identify the species of the subject based on a test result of the genomic test based on the third AI model.

12. The system of claim 11, wherein to determine the first confidence level of the morphological group of the subject, the memory causes the processor to:
determine a highest confidence level of the morphological group among a plurality of confidence levels corresponding to a plurality of morphological groups, the highest confidence level comprising the first confidence level.

13. The system of claim 11, wherein the memory further causes the processor to:
determine the second AI model among a plurality of AI models corresponding a plurality morphological groups based on the morphological group of the subject.

14. The system of claim 12, wherein the memory further causes the processor to:
apply the one or more runtime images to the first AI model; and
receive a plurality of confidence levels corresponding to the plurality of morphological groups, the first confidence level being included in the plurality of confidence levels.

15. The system of claim 11, wherein the memory further causes the processor to:
apply the morphological group, the one or more runtime images, and one or more contextual features to the second AI model, and
receive the second confidence level of the species of the subject based on the morphological group, the one or more runtime images, and the one or more contextual features.

16. The system of claim 15, wherein the one or more contextual features comprises metadata of the one or more runtime images.

17. The system of claim 15, wherein the one or more contextual features comprises at least one of: a location at which the one or more runtime images was taken, a time at which the one or more runtime images was taken, weather information at which the one or more runtime images was taken, temperature information at which the one or more runtime images was taken, or vessel information.

18. The system of claim 11, wherein to determine the second confidence level of the species of the subject, the memory causes the processor to:
determine a highest confidence level of the species among a plurality of confidence levels corresponding to a plurality of species, the highest confidence level comprising the second confidence level.

19. The system of claim 11, wherein the memory further causes the processor to:
provide a genomic test image of the test result of the genomic test to the third AI model,
wherein the species of the subject is identified based on a prediction result of the third AI model.

20. The system of claim 19, wherein the test result is whether the subject is a same species as a target species.
